(19) United States
(12) Patent Application Publication
(10) Pub. No.: US 2020/0090914 A1
(43) Pub. Date: Mar. 19, 2020

(54) METHODS AND APPARATUS FOR UNIFORMITY CONTROL IN SELECTIVE PLASMA VAPOR DEPOSITION

(71) Applicant: APPLIED MATERIALS, INC., Santa Clara, CA (US)

(72) Inventor: KEITH A MILLER, MOUNTAIN VIEW, CA (US)

(21) Appl. No.: 16/543,883

(22) Filed: Aug. 19, 2019

Related U.S. Application Data
(60) Provisional application No. 62/731,374, filed on Sep. 14, 2018.

(51) Int. Cl. H01J 37/34; H01L 21/02; C23C 14/35; C23C 14/54

(52) U.S. Cl. CPC H01J 37/3405; H01L 21/02631; H01J 37/3423; H01J 2237/332; C23C 14/351; C23C 14/54; H01J 37/3452

(57) ABSTRACT

Methods and apparatus for producing a uniform deposition layer for a selective plasma vapor deposition (PVD) chamber. Flux generated by a cylindrical target is adjusted using a magnetron assembly that controls the amount of flux that passes through a slit in the selective PVD chamber. In some embodiments, a magnetron assembly disposed within the cylindrical has a magnetic field strength that varies along a length of the magnetron assembly. The magnetron assembly disposed within the cylindrical target may have a center height greater than either end such that flux generated during processing for a center region of the cylindrical target is directed away from the opening. In some embodiments, a magnetron assembly disposed within the cylindrical target is rotatable such that flux generated during processing for a center region of the cylindrical target is directed away from the opening or towards the opening.

### CROSS-REFERENCE TO RELATED APPLICATIONS

This application claims benefit of U.S. provisional patent application Ser. No. 62/731,374, filed Sep. 14, 2018 which is herein incorporated by reference in its entirety.

### FIELD

Embodiments of the present principles generally relate to semiconductor processing.

### BACKGROUND

The semiconductor processing industry generally continues to strive for increased uniformity of layers deposited on substrates. For example, with shrinking circuit sizes leading to higher integration of circuits per unit area of the substrate, increased uniformity is generally seen as desired, or required in some applications, in order to maintain satisfactory yields and reduce the cost of fabrication. Various technologies have been developed to deposit layers on substrates in a cost-effective and uniform manner, such as chemical vapor deposition (CVD) or physical vapor deposition (PVD). However, the inventor has observed that with the drive to produce equipment to deposit more uniformly, certain applications may not be adequately served where purposeful deposition is required that is not symmetric or uniform with respect to the given structures being fabricated on a substrate.

Accordingly, the inventor has provided improved methods and apparatus for depositing materials via physical vapor deposition.

### SUMMARY

Methods and apparatus for uniform physical vapor deposition are provided herein.

In some embodiments, a magnetron assembly for a cylindrical target comprises a magnet yoke, a first polarity magnet assembly on the magnet yoke, and a second polarity magnet assembly on the magnet yoke, the second polarity magnet assembly surrounding the first polarity magnet assembly, wherein a magnetic field strength between the first polarity magnet assembly and the second polarity magnet assembly varies along a length of the magnetron assembly such the magnetic field strength is less in a center region of the magnetron assembly than in outer regions of the magnetron assembly.

In some embodiments, the magnetron assembly may further include wherein the first polarity magnet assembly or the second polarity magnet assembly uses magnetic materials with less magnetic field strength in the center region of the magnetron assembly than in the outer regions of the magnetron assembly such that the magnetic field strength along the length of the magnetron assembly varies, wherein the first polarity magnet assembly or the second polarity magnet assembly uses fewer magnetic elements in the center region than in the outer regions such that the magnetic field strength along the length of the magnetron assembly varies, wherein the first polarity magnet assembly or the second polarity magnet assembly uses less magnetic material in the center region than in the outer regions such that the magnetic field strength along the length of the magnetron assembly varies, wherein a spread distance between an upper portion of the second polarity magnet assembly and a lower portion of the second polarity magnet assembly is greater in the center region of the magnetron assembly than in the outer regions of the magnetron assembly such that the magnetic field strength is less in the center region than in the outer regions of the magnetron assembly, wherein the magnetron assembly is arched between a first end and a second end, wherein the magnetron assembly is configured to be rotatable upwards or downwards along a lengthwise central axis such that flux generated during processing for a center portion of the cylindrical target is configurable to be directed away from an opening or towards the opening, wherein magnetic fields between the first polarity magnet assembly and the second polarity magnet assembly form a magnet racetrack with a first outer portion, a second outer portion, and a center portion, wherein the magnetron assembly is configured to be installed in the cylindrical target such that a first arc on an outer surface of the cylindrical target from a top to a bottom of the center portion of the magnet racetrack subtends an angle from a lengthwise center axis of the cylindrical target greater than subtended angles from the lengthwise center axis for a second arc from a top to a bottom of the first outer portion and a third arc from a top to a bottom of the first outer portion of the second outer portion, and/or wherein the first arc from the top to the bottom of the center portion is approximately 120 degrees to approximately 160 degrees.

In some embodiments, a plasma vapor deposition (PVD) chamber may comprise a first housing surrounding a movable substrate support, a second housing above the first housing with an opening between the first housing and the second housing that partially exposes a top surface of the movable substrate support, a cylindrical target disposed in the second housing above, parallel to, and offset from the opening between the first housing and the second housing, and a magnetron assembly disposed within the cylindrical target and having a first polarity magnet assembly on a magnet yoke and a second polarity magnet assembly on the magnet yoke, the second polarity magnet assembly surrounding the first polarity magnet assembly, wherein a magnetic field strength between the first polarity magnet assembly and the second polarity magnet assembly varies along a length of the magnetron assembly such that flux generated during processing is less in a center region of the cylindrical target than in outer regions of the cylindrical target.

In some embodiments, the PVD chamber may further include wherein the first polarity magnet assembly or the second polarity magnet assembly uses magnetic materials with less magnetic field strength in the center region than in the outer regions such that the magnetic field strength along the length of the magnetron assembly varies, wherein the first polarity magnet assembly or the second polarity magnet assembly uses fewer magnets in the center region than in the outer regions such that the magnetic field strength along the length of the magnetron assembly varies, wherein the first polarity magnet assembly or the second polarity magnet assembly uses less magnetic material in the center region than in the outer regions such that the magnetic field strength along the length of the magnetron assembly varies, wherein the magnetron assembly is rotatable about a lengthwise central axis of the cylindrical target, wherein the magnetron assembly is configured to actively rotate about the lengthwise central axis to dynamically adjust flux directed toward the opening, wherein the magnetron assembly is configured to rotate about the lengthwise central axis based on feedback, and/or wherein the magnetron assembly has a first end and a second end and wherein the magnetron assembly is arched between the first end and the second end.

In some embodiments, a plasma vapor deposition (PVD) chamber may comprise a first housing surrounding a movable substrate support, a second housing adjacent the first housing with an opening between the first housing and the second housing that partially exposes a top surface of the movable substrate support, a cylindrical target disposed in the second housing above, parallel to, and offset from the opening between the first housing and the second housing, and a magnetron assembly disposed within the cylindrical target and having a first polarity magnet assembly on a magnet yoke and a second polarity magnet assembly on the magnet yoke, the second polarity magnet assembly surrounding the first polarity magnet assembly, wherein magnetic fields between the first polarity magnet assembly and the second polarity magnet assembly form a magnet racetrack with a first outer portion, a second outer portion, and a center portion, and wherein a first arc on an outer surface of the cylindrical target from a top to a bottom of the center portion of the magnet racetrack subtends an angle from a lengthwise central axis of the cylindrical target greater than subtended angles from the lengthwise central axis for a second arc from a top to a bottom of the first outer portion and a third arc from a top to a bottom of the first outer portion of the second outer portion such that flux generated during processing for a center region of the cylindrical target is directed away from the opening.

In some embodiments, the PVD chamber may further include wherein the magnetron assembly is configured to rotate about the lengthwise central axis and/or wherein the magnetron assembly is configured to rotate upwards or downwards about the lengthwise central axis to actively adjust flux directed toward the opening.

Other and further embodiments are disclosed below.

### BRIEF DESCRIPTION OF THE DRAWINGS

Embodiments of the present principles, briefly summarized above and discussed in greater detail below, can be understood by reference to the illustrative embodiments of the principles depicted in the appended drawings. However, the appended drawings illustrate only typical embodiments of the principles and are thus not to be considered limiting of scope, for the principles may admit to other equally effective embodiments.

FIG. 1 is a cross-sectional view of a selective PVD chamber in accordance with some embodiments of the present principles.

FIG. 2 is an isometric view of a cylindrical target in accordance with some embodiments of the present principles.

FIG. 3 is a top view of a magnetron assembly for a cylindrical target in accordance with some embodiments of the present principles.

FIG. 4 is a top view of a magnetron assembly with an adjusted magnetic field for a cylindrical target in accordance with some embodiments of the present principles.

FIG. 5 is a top view of a magnetron assembly with an adjusted geometry for a cylindrical target in accordance with some embodiments of the present principles.

FIG. 6 is an isometric view of a cylindrical target with the magnet racetrack of FIG. 5 in accordance with some embodiments of the present principles.

FIG. 7 is an isometric view of sputtering projection for a cylindrical target with an adjusted geometry magnetron assembly in accordance with some embodiments of the present principles.

FIG. 8 is an isometric view of the cylindrical target with a magnet racetrack in accordance with some embodiments.

FIG. 9 is a cross-sectional view of a wobble/tilt magnetron assembly in a cylindrical target in accordance with some embodiments of the present principles.

FIG. 10 is a top view of a wobble/tilt magnetron assembly that may be used with a cylindrical target of FIG. 8 in accordance with some embodiments of the present principles.

FIG. 11 is a graph depicting deposition uniformity across a surface of a substrate in accordance with some embodiments of the present principles.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

The methods and apparatus provide increased uniformity in plasma vapor deposition (PVD) for semiconductor applications. In some applications, a selective PVD apparatus is used to deposit material on the sidewalls of features found on a substrate. The selective PVD process uses a cylindrical target that generates plasma at an angle towards an opening or slit in a collimation plate. The angle of sputtered deposition material from the target to the surface of the substrate results in plasma deposition on the sidewalls of the substrate features. The inventor has found that a selective PVD apparatus generates a deposition layer that is thicker in the middle of the substrate when compared to the outer edges of the substrate. The inventor has also found that lengthening a cylindrical target used in the selective PVD apparatus increases the uniformity but is impractical in actual operating scenarios due to the cylindrical target length needing to be substantially greater than a diameter of a substrate to increase deposition uniformity. The optimal length of the cylindrical target would require a much larger PVD chamber to accommodate such a target making such a chamber uneconomical. The inventor has discovered that adjusting the magnet strength of a magnetron assembly and/or magnet shape along a length of a cylindrical target can also control deposition uniformity in a static fashion without being cost prohibitive. In addition, a tilt/wobble axis and/or non-rectangular magnets can also be used as tuning parameters to actively control uniformity during deposition processes.

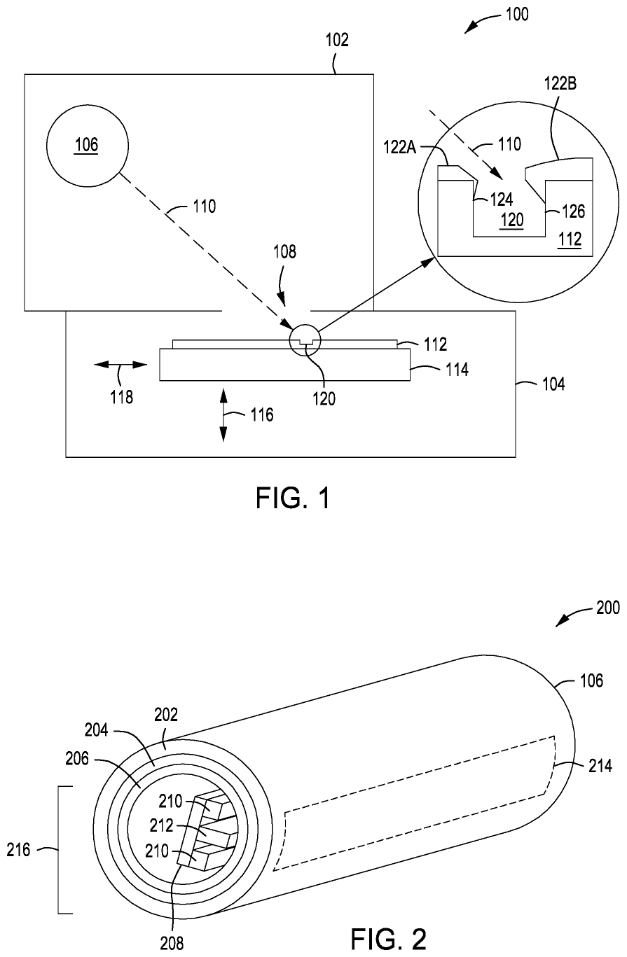

FIG. 1 is a cross-sectional view of a selective PVD chamber 100 in accordance with some embodiments. The selective PVD chamber 100 has an upper housing 102 and a lower housing 104. The upper housing 102 includes a cylindrical target 106 that produces plasma 110 directed to an opening 108 (or slit) between the upper housing 102 and the lower housing 104. The lower housing 104 includes a substrate support 114 that may be movable in a vertical direction 116 and/or in a horizontal direction 118. Material from the cylindrical target 106 is sputtered by the plasma 110 through the opening 108 at an angle and onto a substrate 112 on the substrate support 114. The substrate 112 may have a feature 120 where a first deposition area 122A and a second deposition area 122B from the plasma 110 are selectively deposited on the feature 120. Due to the angle of the plasma 110, the first deposition area 122A may only encroach slightly on a first side 124 of the feature 120, whereas the second deposition area 122B includes a larger deposition on a second side 126 of the feature. The angle of the plasma 110 allows for selective deposition into features. Different areas of the substrate 112 that are not currently exposed by the opening 108 may be reached by moving the substrate support 114 horizontally and/or vertically during deposition processes.

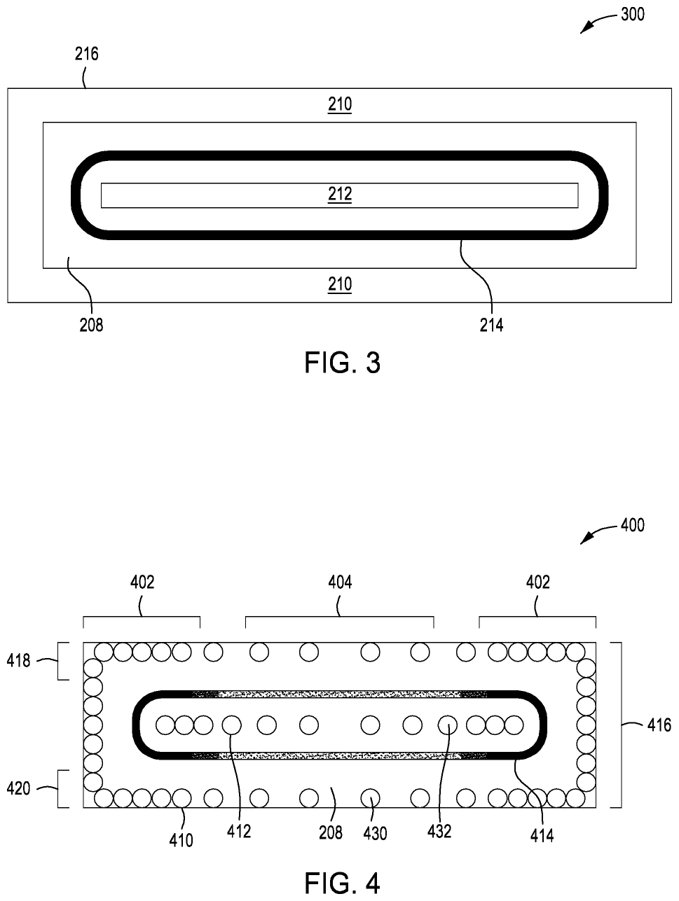

FIG. 2 is an isometric view 200 of the cylindrical target 106 in accordance with some embodiments. The cylindrical target 106 may include a sputtering material layer 202, a backing layer 204 for supporting the sputtering material layer 202, and a cooling passage 206 for cooling the cylindrical target 106. Inside the cylindrical target 106 is a magnetron assembly 216 that generates a magnetic field perpendicular to the surface of the cylindrical target. The magnetic field forms plasma that sputters material from the cylindrical target 106 which is then deposited on the substrate 112 through the opening 108. The magnetron assembly 216 includes a magnet yoke 208 that supports a first polarity magnet set 210 and a second polarity magnet set 212. The first polarity magnet set 210 and the second polarity magnet set 212 have different polarities (e.g., north/south or south/north). In some embodiments, the first polarity magnet set 210 may have one or more magnets. In some embodiments, the second polarity magnet set 212 may have one or more magnets. In some embodiments, the first polarity magnet set 210 and/or the second polarity magnet set 212 may be formed from a magnetic material (such as, but not limited to, neodymium, etc.) and/or be electromagnets. In FIG. 2, the first polarity magnet set 210 is shown in a cross-sectional view as a separate upper and lower magnet set for ease of understanding. In some embodiments, the first polarity magnet set 210 forms a ring around the second polarity magnet set 212 (not shown in FIG. 2, see, for example, FIGS. 3-5 and 10). The space between the first polarity magnet set 210 and the second polarity magnet set 212 forms a magnetic field. The magnetic field may form a shape similar to a racetrack and is known as a magnet racetrack 214. The magnet racetrack 214 is the area on the surface of the cylindrical target 106 where plasma is generated and material is sputtered perpendicular to the surface of the cylindrical target 106. In some embodiments, the cylindrical target 106 may revolve around the magnetron assembly 216 to evenly erode the surface of the cylindrical target 106 during deposition.

FIG. 3 is a top view 300 of the magnetron assembly 216 for the cylindrical target 106 in accordance with some embodiments. The magnet yoke 208 provides support for the first polarity magnet set 210 and the second polarity magnet set 212. In some embodiments, the first polarity magnet set 210 forms a ring around the second polarity magnet set 212. The magnet racetrack 214 forms between the first polarity magnet set 210 and the second polarity magnet set 212. The inventor has found that near the ends of the magnetron assembly 216 the flux generated by the magnet racetrack 214 does not reach the substrate as well as the flux generated near the center of the magnet racetrack 214, causing less deposition material on the edges of the substrate 112. As discussed above, if the cylindrical target 106 is drastically increased in length to move the ends of the magnet racetrack 214 further out from the edges of the substrate to increase deposition uniformity, the selective PVD chamber size would be economically prohibitive.

FIG. 4 is a top view 400 of a magnetron assembly 416 with an adjusted magnetic field strength for the cylindrical target 106 in accordance with some embodiments. In some embodiments, a first polarity magnet set 410 uses individual magnetic elements 430 placed on the magnet yoke 208 with an increased density of magnetic elements at outer portions 402 of the magnetron assembly 416 compared to the density of magnetic elements in a center portion 404 of the magnetron assembly 416. In some embodiments, a second polarity magnet set 412 uses individual magnetic elements 432 placed on the magnet yoke 208 with an increased density of magnetic elements 432 at the outer portions 402 of the magnetron assembly 416 compared to the density of magnetic elements 432 in the center portion 404 of the magnetron assembly 416. In some embodiments, the first polarity magnet set 410 and the second polarity magnet set 412 use magnetic elements 430, 432 placed on the magnet yoke 208 with an increased density of magnetic elements 430, 432 at the outer portions 402 of the magnetron assembly 416 compared to the density of magnetic elements 430, 432 in the center portion 404 of the magnetron assembly 416. In some embodiments, the density of magnetic elements 430 of the first polarity magnet set 410 may be different on an upper region 418 of the first polarity magnet set 410 compared to a lower region 420 of the first polarity magnet set 410. By adjusting the distribution of the magnetic elements 430, 432 in the first polarity magnet set 210 and/or the second polarity magnet set 212, the magnetic field strength of a magnet racetrack 414 may be varied (shown by the gradient shading) along the length of the magnet racetrack 414 to increase the magnetic field strength near the outer portions 402 of the magnetron assembly 416 and decrease the magnetic field strength in the center portion 404 of the magnetron assembly 416. In some embodiments, the magnetron assembly 416 may be advantageously reconfigurable such that the magnetic field strength may be varied by inserting and/or removing magnetic elements 430, 432 of the first polarity magnet set 410 and/or the second polarity magnet set 412.

In some embodiments, the magnetic field strength may be varied by using magnet materials with varying magnetic field strengths and/or using less magnet material in the center portion 404. The inventor has found that for an approximately 700 mm long cylindrical target that is positioned approximately 350 mm from a 300 mm substrate, a ratio of 2:1 of magnetic strength at the outer portions 402 to magnetic strength at the center portion 404 provides for an approximately uniform deposition of material on the substrate.

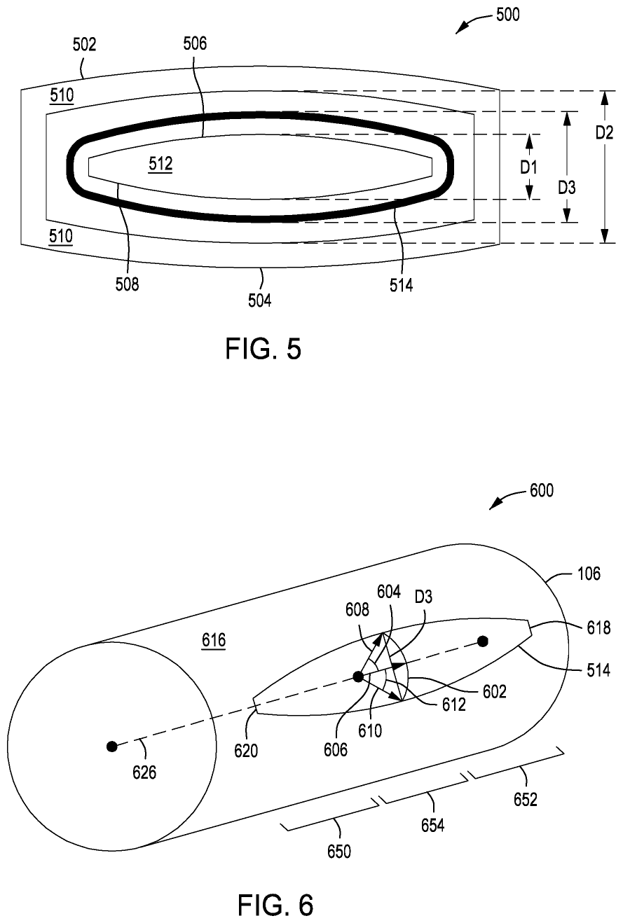

FIG. 5 is a top view of a magnetron assembly 500 with an adjusted geometry for a cylindrical target in accordance with some embodiments. In some embodiments, a magnet racetrack 514 may be adjusted outward (spread distance D3) in a central area of a cylindrical target to effectively reduce an amount of sputtering that reaches a central region of a substrate through a slit or opening. When a cylindrical target is sputtered, the magnetron assembly forms a magnetic field that guides the flux outward in a perpendicular direction relative to the surface of the cylindrical target. If a slit or opening is aligned with the magnetron assembly, a majority of the flux produced perpendicular to the surface of the cylindrical target will pass through the slit to the surface of a substrate. The inventor has found that the amount of flux passing through the center region of the slit may be controlled by increasing a spread distance D2 between) an upper portion of a magnet assembly with a first polarity and a lower portion of the magnet assembly with the first polarity. The spreading of the center of the magnet assembly with the first polarity causes a magnetic field to form which produces perpendicular flux that is no longer aligned with the slit and does not reach the surface of substrate. Adjustments to the spread distance D2 may be made to increase or decrease an amount of deposition material that forms on a central region of a substrate. A spreading distance D1 of the magnet assembly with a second polarity may also be increased. The reduction of flux passing through the slit in a central region helps compensate for the finite length of the cylindrical target. In some embodiments, an upper region of a first polarity magnet assembly 510 may include an upper arch 502 and/or a lower region of the first polarity magnet assembly 510 may include a lower arch 504. In some embodiments, an upper region of a second polarity magnet assembly 512 may include an upper arch 506 and/or a lower region of the second polarity magnet assembly 512 may include a lower arch 508. Other shapes besides arches may be used for the first polarity magnet assembly 510 and/or the second polarity magnet assembly to reduce an amount of flux that reaches a central region of a substrate through a slit or opening.

FIG. 6 is an isometric view 600 of the cylindrical target 106 with the magnet racetrack 514 of FIG. 5 in accordance with some embodiments. The spread distance D3 of the magnet racetrack 514 of FIG. 5 is actually a chord of an arc 602 transcribed on an outer surface 616 of the cylindrical target 106. A first angle 604 about a central axis 626 of the cylindrical target 106 from a tangent line 606 with respect to the outer surface 616 of the cylindrical target 106 to an upper boundary line 608 delineates an upper half of the spread distance D3. A second angle 612 about the central axis 626 of the cylindrical target 106 from the tangent line 606 to a lower boundary line 610 delineates the lower half of the spread distance D3. In some embodiments, the first angle 604 and the second angle 612 may be equal or different. The spread distance D3 of the magnet racetrack 514 is the length of the chord of the end points of the arc 602. The chord (D3)=2×radius×sin(arc length/(2×radius)). In the embodiment of FIG. 5, a center portion 654 of the magnet racetrack 514 has an arc length greater than an arc length of a first end portion arc 618 of a first end portion 652 and an arc length of a second end portion arc 620 of a second end portion 650. The magnet racetrack 514 may be adjusted by changing the shape of the first polarity magnet assembly 510 and/or the second polarity magnet assembly 512.

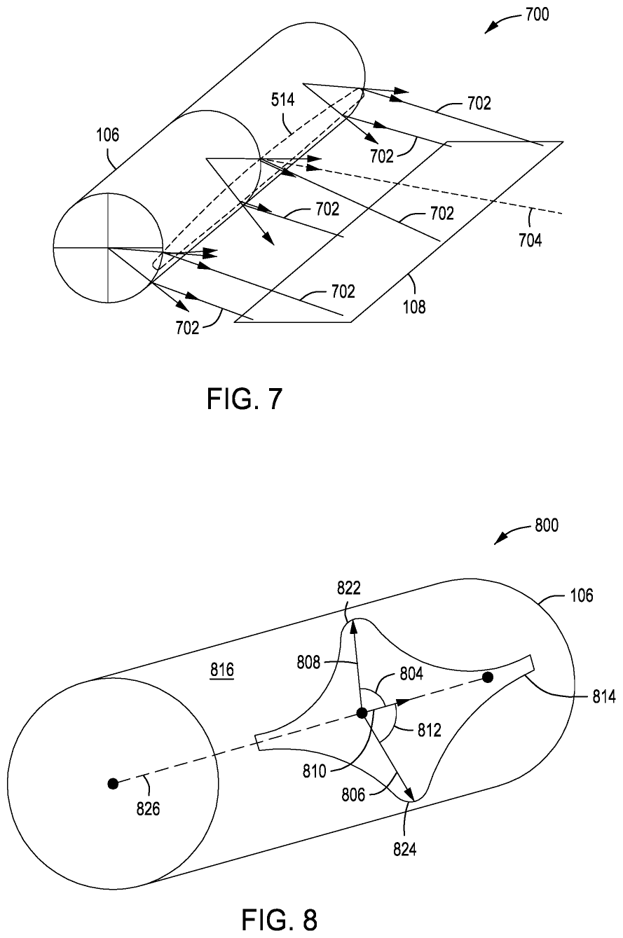

FIG. 7 is an isometric view 700 of sputtering projection for a cylindrical target with an adjusted geometry magnetron assembly in accordance with some embodiments. As described above for FIG. 5, the magnet racetrack 514 has been adjusted outward (spread apart) in a central region. The cylindrical target 106 when sputtered produces sputtering material (flux) in perpendicular directions that fall outside of the opening 108 of FIG. 1. First sputtering projections 702 pass through the opening 108 and deposit material on the substrate 112. In the central region of the magnet racetrack 514 that is adjusted outward, the second sputtering projections 704 are outside of the opening 108 and do not deposit material on the substrate 112. As the magnet racetrack 514 is adjusted further outward, even less material is deposited on a central region of the substrate 112. The outward adjustment (spreading) of the magnet racetrack 514 allows control of the uniformity of the deposition on the substrate 112 by controlling the amount of material deposited in the central region of the substrate 112.

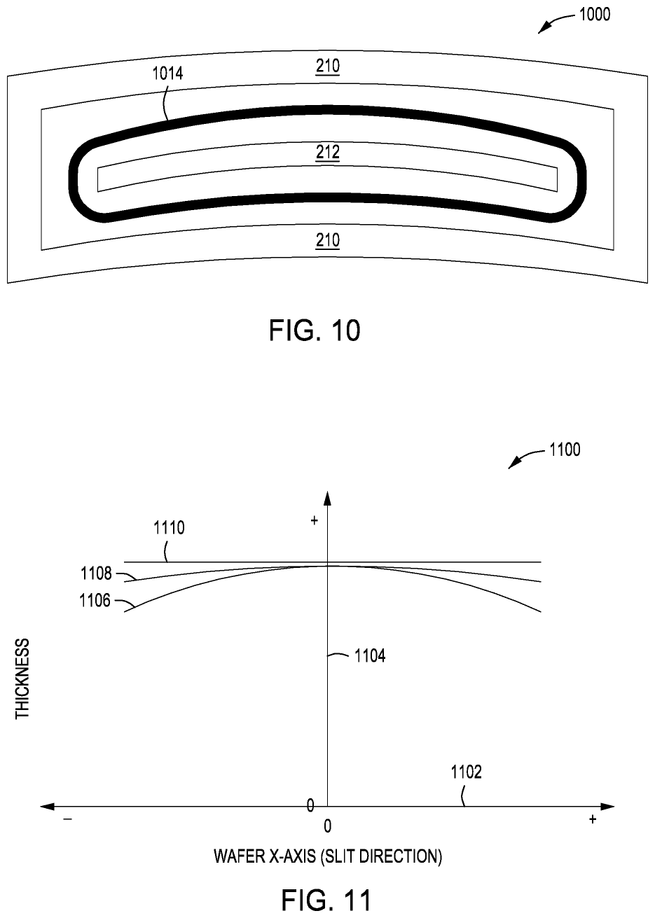

FIG. 8 is an isometric view of the cylindrical target 106 with a magnet racetrack 814 in accordance with some embodiments. In some embodiments, the amount of flux reaching areas of the substrate 112 is further controlled by forming bends or protrusions in a magnet racetrack. In FIG. 8, the magnet racetrack 814 includes a first protrusion 822 and a second protrusion 824. The first protrusion 822 of the magnet racetrack 814 rotates upward around a central axis 826 of the cylindrical target 106 to an upper boundary line 808. In some embodiments, a first rotation angle 804 produced by a central tangent line 810 to a surface 816 of the cylindrical target 106 and the upper boundary line 808 is approximately 60 degrees to approximately 80 degrees. The second protrusion 824 of the magnet racetrack 814 rotates downward around the central axis 826 of the cylindrical target 106 to a lower boundary line 806. In some embodiments, a second rotation angle 812 produced by the central tangent line 810 and the upper boundary line 808 is approximately 60 degrees to approximately 80 degrees. In some embodiments, the first rotation angle 804 and the second rotation angle 812 may have a combined rotation angle of approximately 120 degrees to approximately 180 degrees. In some embodiments, the magnet racetrack 814 may have only a first protrusion 822 or only a second protrusion 824. The first protrusion 822 and the second protrusion 824 extend the magnet racetrack 814 such that less flux passes through the opening 108 of FIG. 1 and onto a central area of the substrate 112, controlling the amount of deposition in the central area and creating a uniform deposition layer. In some embodiments, the first protrusion 822 and/or the second protrusion 824 may be added to other magnet racetrack shapes such as that described below for FIG. 10.

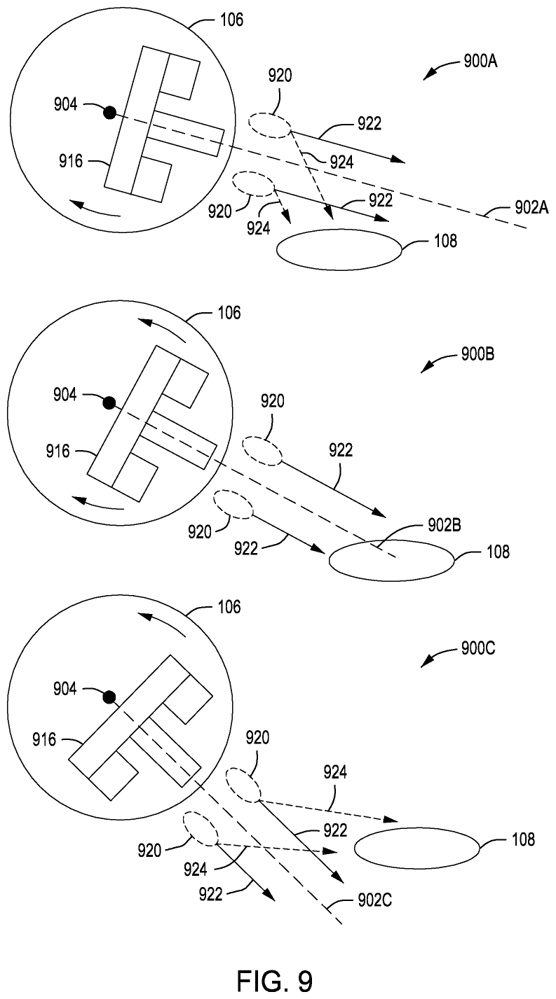

FIG. 9 is a cross-sectional view of a wobble/tilt magnetron assembly 916 in the cylindrical target 106 in accordance with some embodiments. The wobble/tilt magnetron assembly 916 rotates upwards and/or downwards (e.g., wobbles, tilts, etc.) about an axis 904 of the cylindrical target 106. In view 900A, the wobble/tilt magnetron assembly 916 is directed in a direction 902A such that perpendicular flux 922 produced by plasma 920 at the surface of the cylindrical target 106 is aimed above the opening 108 of FIG. 1. Non-perpendicular flux 924 may reach the opening 108. In view 900B, the wobble/tilt magnetron assembly 916 is directed in a direction 902B such that perpendicular flux 922 produced at the surface of the cylindrical target 106 is aimed into the opening 108 of FIG. 1. In view 900C, the wobble/tilt magnetron assembly 916 is directed in a direction 902C such that perpendicular flux 922 produced at the surface of the cylindrical target 106 is aimed below the opening 108 of FIG. 1. Non-perpendicular flux 924 may reach the opening 108. As the wobble/tilt magnetron assembly 916 is moved to different positions or angles relative to the slit or opening 108, varying amounts of deposition occur across the surface of the substrate 112. In some embodiments, the wobble/tilt magnetron assembly 916 is used to statically adjust deposition amounts on the substrate 112. In some embodiments, the wobble/tilt magnetron assembly 916 is actively moved during deposition to provide varying amounts of deposition on the substrate as the substrate is scanned (e.g., moved horizontally and/or vertically). In some embodiments, the wobble/tilt magnetron assembly 916 is moved based on a position of the opening 108 relative to an exposed area of the surface of the substrate 112.

FIG. 10 is a top view of a wobble/tilt magnetron assembly 1000 that may be used with the cylindrical target of FIG. 9 in accordance with some embodiments. The wobble/tilt magnetron assembly 1000 includes arched upper and lower regions of the first polarity magnet set 210 and the second polarity magnet set 212. The shape of the resulting magnet racetrack 1014 controls sputtering material directed towards the opening 108 of FIG. 1. As the wobble/tilt magnetron assembly 1000 is rotated upwards and/or downwards to different positions, the amount of sputtered material (flux) reaching the surface of the substrate 112 is altered.

When the wobble/tilt magnetron assembly 1000 is positioned as shown in view 900A of FIG. 9, most of the magnet racetrack 1014 is aligned with the opening 108 causing greater deposition in the central region of the substrate 112. When the wobble/tilt magnetron assembly 1000 is positioned as shown in view 900B of FIG. 9, less deposition of material occurs in the central region of the substrate 112, increasing uniformity of the deposition material. When the wobble/tilt magnetron assembly 1000 is positioned as shown in View 900C of FIG. 9, even less deposition of material occurs in the central region of the substrate 112, further increasing uniformity of the deposition material. The shape of the wobble/tilt magnetron assembly 1000 and the positioning of the wobble/tilt magnetron assembly affect the deposition uniformity across the surface of the substrate. The rotation adjustment allows for fine tuning of deposition uniformity in a selective PVD chamber without requiring equipment changes or laborious testing.

FIG. 11 is a graph 1100 depicting deposition uniformity across a surface of the substrate 112 in accordance with some embodiments. The x-axis 1102 represents the outward distance across a surface of the substrate 112 with the zero point representing the center of the substrate 112. The y-axis 1104 represents the thickness of deposited material on the surface of the substrate 112. A first deposition thickness line 1106 represents deposition processes where the plasma formation process has not been adjusted for central region uniformity of the substrate 112. The first deposition thickness line 1106 shows that the deposition layer is thickest at the center point of the substrate 112 and thinner at the edges of the substrate 112. A second deposition thickness line 1108 indicates that adjustments have been made to increase the deposition towards the outer edges of the substrate 112. As discussed above, improvements in thickness may be achieved by increasing magnetic strength at the edges while decreasing magnetic strength in the center of a magnetron assembly and/or by altering the shape of the magnet racetrack and/or by moving the position of the magnetron assembly relative to the opening 108 to the substrate 112. A third deposition thickness line 1110 depicts approximately uniformity across the surface of the substrate 112. The methods used to improve the second deposition thickness line 1108 may be further fine-tuned to achieve the increased uniformity of the deposition material on the substrate for the third deposition thickness line 1110.

While the foregoing is directed to embodiments of the present principles, other and further embodiments of the principles may be devised without departing from the basic scope thereof.

1. A magnetron assembly for a cylindrical target, comprising:
a magnet yoke;
a first polarity magnet assembly on the magnet yoke; and
a second polarity magnet assembly on the magnet yoke, the second polarity magnet assembly surrounding the first polarity magnet assembly,
wherein a magnetic field strength between the first polarity magnet assembly and the second polarity magnet assembly varies along a length of the magnetron assembly such the magnetic field strength is less in a center region of the magnetron assembly than in outer regions of the magnetron assembly.

2. The magnetron assembly of claim 1, wherein the first polarity magnet assembly or the second polarity magnet assembly uses magnetic materials with less magnetic field strength in the center region of the magnetron assembly than in the outer regions of the magnetron assembly such that the magnetic field strength along the length of the magnetron assembly varies.

3. The magnetron assembly of claim 1, wherein the first polarity magnet assembly or the second polarity magnet assembly uses fewer magnetic elements in the center region than in the outer regions such that the magnetic field strength along the length of the magnetron assembly varies.

4. The magnetron assembly of claim 1, wherein the first polarity magnet assembly or the second polarity magnet assembly uses less magnetic material in the center region than in the outer regions such that the magnetic field strength along the length of the magnetron assembly varies.

5. The magnetron assembly of claim 1, wherein a spread distance between an upper portion of the second polarity magnet assembly and a lower portion of the second polarity magnet assembly is greater in the center region of the magnetron assembly than in the outer regions of the magnetron assembly such that the magnetic field strength is less in the center region than in the outer regions of the magnetron assembly.

6. The magnetron assembly of claim 1, wherein the magnetron assembly is arched between a first end and a second end.

7. The magnetron assembly of claim 1, wherein the magnetron assembly is configured to be rotatable upwards or downwards along a lengthwise central axis such that flux generated during processing for a center portion of the cylindrical target is configurable to be directed away from an opening or towards the opening.

8. The magnetron assembly of claim 1, wherein magnetic fields between the first polarity magnet assembly and the second polarity magnet assembly form a magnet racetrack with a first outer portion, a second outer portion, and a center portion, and
wherein the magnetron assembly is configured to be installed in the cylindrical target such that a first arc on an outer surface of the cylindrical target from a top to a bottom of the center portion of the magnet racetrack subtends an angle from a lengthwise center axis of the cylindrical target greater than subtended angles from the lengthwise center axis for a second arc from a top to a bottom of the first outer portion and a third arc from a top to a bottom of the first outer portion of the second outer portion.

9. The magnetron assembly of claim 8, wherein the first arc from the top to the bottom of the center portion is approximately 120 degrees to approximately 160 degrees.

10. A plasma vapor deposition (PVD) chamber, comprising:
a first housing surrounding a movable substrate support;
a second housing above the first housing with an opening between the first housing and the second housing that partially exposes a top surface of the movable substrate support;
a cylindrical target disposed in the second housing above, parallel to, and offset from the opening between the first housing and the second housing; and
a magnetron assembly disposed within the cylindrical target and having a first polarity magnet assembly on a magnet yoke and a second polarity magnet assembly on the magnet yoke, the second polarity magnet assembly surrounding the first polarity magnet assembly, wherein a magnetic field strength between the first polarity magnet assembly and the second polarity magnet assembly varies along a length of the magnetron assembly such that flux generated during processing is less in a center region of the cylindrical target than in outer regions of the cylindrical target.

11. The PVD chamber of claim 10, wherein the first polarity magnet assembly or the second polarity magnet assembly uses magnetic materials with less magnetic field strength in the center region than in the outer regions such that the magnetic field strength along the length of the magnetron assembly varies.

12. The PVD chamber of claim 10, wherein the first polarity magnet assembly or the second polarity magnet assembly uses fewer magnets in the center region than in the outer regions such that the magnetic field strength along the length of the magnetron assembly varies.

13. The PVD chamber of claim 10, wherein the first polarity magnet assembly or the second polarity magnet assembly uses less magnetic material in the center region than in the outer regions such that the magnetic field strength along the length of the magnetron assembly varies.

14. The PVD chamber of claim 10, wherein the magnetron assembly is rotatable about a lengthwise central axis of the cylindrical target.

15. The PVD chamber of claim 14, wherein the magnetron assembly is configured to actively rotate about the lengthwise central axis to dynamically adjust flux directed toward the opening.

16. The PVD chamber of claim 14, wherein the magnetron assembly is configured to rotate about the lengthwise central axis based on feedback.

17. The PVD chamber of claim 10, wherein the magnetron assembly has a first end and a second end and wherein the magnetron assembly is arched between the first end and the second end.

18. A plasma vapor deposition (PVD) chamber, comprising:
a first housing surrounding a movable substrate support;
a second housing adjacent the first housing with an opening between the first housing and the second housing that partially exposes a top surface of the movable substrate support;
a cylindrical target disposed in the second housing above, parallel to, and offset from the opening between the first housing and the second housing; and
a magnetron assembly disposed within the cylindrical target and having a first polarity magnet assembly on a magnet yoke and a second polarity magnet assembly on the magnet yoke, the second polarity magnet assembly surrounding the first polarity magnet assembly, wherein magnetic fields between the first polarity magnet assembly and the second polarity magnet assembly form a magnet racetrack with a first outer portion, a second outer portion, and a center portion, and wherein a first arc on an outer surface of the cylindrical target from a top to a bottom of the center portion of the magnet racetrack subtends an angle from a lengthwise central axis of the cylindrical target greater than subtended angles from the lengthwise central axis for a second arc from a top to a bottom of the first outer portion and a third arc from a top to a bottom of the first outer portion of the second outer portion such that flux generated during processing for a center region of the cylindrical target is directed away from the opening.

19. The PVD chamber of claim 18, wherein the magnetron assembly is configured to rotate about the lengthwise central axis.

20. The PVD chamber of claim 19, wherein the magnetron assembly is configured to rotate upwards or downwards about the lengthwise central axis to actively adjust flux directed toward the opening.
